(19) United States
(12) Patent Application Publication
(10) Pub. No.: US 2026/0068605 A1
(43) Pub. Date: Mar. 5, 2026

(54) SEMICONDUCTOR DEVICE AND MANUFACTURING METHOD THEREOF

(71) Applicant: Kioxia Corporation, Tokyo (JP)

(72) Inventor: Takashi WATANABE, Yokkaichi (JP)

(73) Assignee: Kioxia Corporation, Tokyo (JP)

(21) Appl. No.: 19/045,635

(22) Filed: Feb. 5, 2025

(30) Foreign Application Priority Data
Sep. 3, 2024 (JP) 2024-151603

(51) Int. Cl. H01L 21/66; H01L 23/00; H01L 25/065; H10B 43/20; H10B 43/40; H10B 80/00

(52) U.S. Cl. CPC H01L 22/12; H10B 43/40; H10B 80/00; H10B 43/20

(57) ABSTRACT

A semiconductor device according to the present embodiment includes a structural body and a light blocker. At a measurement site that is irradiated with measurement light to measure a structure of the structural body, the light blocker is provided at a position farther than the structural body in an advancing direction of the measurement light with which irradiation is performed, and the light blocker blocks the measurement light. The light blocker includes first metal layers in two or more layers.

### CROSS REFERENCE TO RELATED APPLICATIONS

This application is based upon and claims the benefit of priority from the prior Japanese Patent Application No. 2024-151603, filed on Sep. 3, 2024, the entire contents of which are incorporated herein by reference.

### FIELD

The embodiments of the present invention relate to a semiconductor device and a manufacturing method thereof.

### BACKGROUND

In a process for manufacturing a semiconductor device, to control quality in processes, such as a film forming process, a chemical mechanical polishing (CMP) process, or an etching process, the film thicknesses of insulation films and the thicknesses of wiring layers at a measurement site provided in advance are optically measured in general. However, in recent years, in semiconductor devices having complicated structures, represented by a three-dimensional flash memory, there may be cases in which a spectrum is complicated by an increased spectrum oscillation caused by interference of an insulation film having a large thickness or is complicated by reflected light from a large number of interface layers, for example. The complicated spectrum makes it difficult to form a measurement recipe, and increases time for measurement, thus causing a problem.

### BRIEF DESCRIPTION OF THE DRAWINGS

FIG. 1 is a cross sectional view showing one example of the structure of a semiconductor device;

FIG. 2 is a cross sectional view showing one example of the structure of a column;

FIG. 3 is a top plan view showing one example of the configuration of the semiconductor device according to a first embodiment;

FIG. 4A is a cross sectional view showing one example of the configuration of the semiconductor device according to the first embodiment;

FIG. 4B is a cross sectional view showing one example of the configuration of the semiconductor device according to the first embodiment;

FIG. 5A is a top plan view showing one example of the configuration of a light blocking structure according to the first embodiment;

FIG. 5B is a top plan view showing one example of the configuration of a light blocking structure according to the first embodiment;

FIG. 6 is a top plan view showing one example of the configuration of upper layer wirings according to the first embodiment;

FIG. 7 is a top plan view showing one example of the configuration of the semiconductor device according to the first embodiment;

FIG. 8A is a cross sectional view showing one example of a method for manufacturing a semiconductor device according to the first embodiment;

FIG. 8B is a cross sectional view showing one example of the method for manufacturing a semiconductor device, subsequent to FIG. 8A;

FIG. 9 is a cross sectional view showing one example of the configuration of a semiconductor device according to a second embodiment;

FIG. 10A is a top plan view showing one example of the configuration of a light blocking structure according to the second embodiment;

FIG. 10B is a top plan view showing one example of the configuration of a light blocking structure according to the second embodiment;

FIG. 10C is a top plan view showing one example of the configuration of a light blocking structure according to the second embodiment;

FIG. 11A is a top plan view showing one example of the configuration of a light blocking structure according to a third embodiment;

FIG. 11B is a top plan view showing one example of the configuration of a light blocking structure according to the third embodiment;

FIG. 11C is a top plan view showing one example of the configuration of a light blocking structure according to the third embodiment;

FIG. 12 is a cross sectional view showing one example of the configuration of a semiconductor device according to a fourth embodiment;

FIG. 13A is a cross sectional view showing one example of the configuration of a light blocking structure according to the fourth embodiment;

FIG. 13B is a cross sectional view showing one example of the configuration of a light blocking structure according to the fourth embodiment;

FIG. 14 is a cross sectional view showing one example of the configuration of a semiconductor device according to a fifth embodiment;

FIG. 15 is a cross sectional view showing one example of the configuration of a semiconductor device according to a sixth embodiment;

FIG. 16 is a top plan view showing one example of the configuration of a light blocking structure according to a seventh embodiment;

FIG. 17 is a cross sectional view showing one example of the configuration of a semiconductor device according to an eighth embodiment;

FIG. 18A is a cross sectional view showing one example of a method for manufacturing a semiconductor device according to a ninth embodiment;

FIG. 18B is a cross sectional view showing one example of the method for manufacturing a semiconductor device, subsequent to FIG. 18A;

FIG. 19 is a cross sectional view showing one example of the configuration of a semiconductor device according to a tenth embodiment; and

FIG. 20 is a cross sectional view showing one example of the configuration of a semiconductor device according to an eleventh embodiment.

### DETAILED DESCRIPTION

Embodiments will now be explained with reference to the accompanying drawings. The present invention is not limited to the embodiments. It should be noted that the drawings are schematic or conceptual, and the relationship between the thickness and the width in each element and the ratio among the dimensions of elements do not necessarily match the actual ones. Even if two or more drawings show the same portion, the dimensions and the ratio of the portion may differ in each drawing. In the present specification and the drawings, elements identical to those described in the foregoing drawings are denoted by like reference characters and detailed explanations thereof are omitted as appropriate.

A semiconductor device according to the present embodiment includes a structural body and a light blocker. At a measurement site that is irradiated with measurement light to measure a structure of the structural body, the light blocker is provided at a position farther than the structural body in an advancing direction of the measurement light with which irradiation is performed, and the light blocker blocks the measurement light. The light blocker includes first metal layers in two or more layers.

### First Embodiment

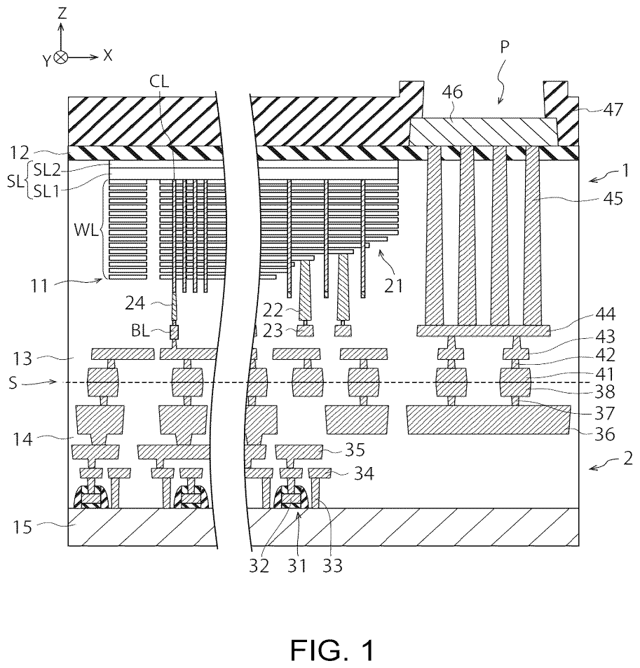

FIG. 1 is a cross sectional view showing one example of the structure of a semiconductor device. The semiconductor device shown in FIG. 1 is a three-dimensional memory in which an array chip 1 and a circuit chip 2 are bonded to each other. The array chip 1 is an example of a first chip, and the circuit chip 2 is an example of a second chip.

The array chip 1 includes a memory cell array 11, an insulation film 12, and an interlayer insulation film 13, the memory cell array 11 including a plurality of memory cells, the insulation film 12 being disposed above the memory cell array 11, the interlayer insulation film 13 being disposed below the memory cell array 11. The insulation film 12 is a silicon oxide film or a silicon nitride film, for example. The interlayer insulation film 13 is, for example, a silicon oxide film, or a laminated film including a silicon oxide film and other insulation films.

The circuit chip 2 is provided below the array chip 1. Symbol “S” denotes a bonding surface between the array chip 1 and the circuit chip 2. The bonding surface S is an example of a first bonding surface. The circuit chip 2 includes an interlayer insulation film 14, and a substrate 15 disposed below the interlayer insulation film 14. The interlayer insulation film 14 is, for example, a silicon oxide film, or a laminated film including a silicon oxide film and other insulation films. The substrate 15 is, for example, a semiconductor substrate, such as a silicon substrate.

FIG. 1 shows the X direction, the Y direction, and the Z direction, the X direction and the Y direction being parallel to the surface of the substrate 15 and being perpendicular to each other, the Z direction being perpendicular to the surface of the substrate 15. In this specification, the +Z direction is taken as the upward direction, and the −Z direction is taken as the downward direction. The −Z direction may or may not align with the gravity direction.

The array chip 1 includes, as electrode layers in the memory cell array 11, a plurality of word lines WL and a source line SL. FIG. 1 shows a stair structure 21 of the memory cell array 11. Each word line WL is electrically connected to a word wiring layer 23 via a contact plug 22. Each of columns CL that penetrate through the plurality of word lines WL is electrically connected to a bit line BL via a via plug 24, and is electrically connected to the source line SL. The source line SL includes a first layer SL1, which serves as a semiconductor layer, and a second layer SL2, which serves as a metal layer.

The circuit chip 2 includes a plurality of transistors 31. Each transistor 31 includes a gate electrode 32, a source diffusion layer, and a drain diffusion layer, the gate electrode 32 being provided on the substrate 15 with a gate insulation film interposed therebetween, the source diffusion layer and the drain diffusion layer being provided in the substrate 15 and not shown in the drawing. The circuit chip 2 also includes a plurality of contact plugs 33, a wiring layer 34, and a wiring layer 35, the plurality of contact plugs 33 being provided on the gate electrodes 32, the source diffusion layer, or the drain diffusion layer of these transistors 31, the wiring layer 34 being provided on these contact plugs 33 and including a plurality of wirings, the wiring layer 35 being provided above the wiring layer 34 and including a plurality of wirings.

The circuit chip 2 further includes a wiring layer 36, a plurality of via plugs 37, and a plurality of metal pads 38, the wiring layer 36 being provided above the wiring layer 35 and including a plurality of wirings, the plurality of via plugs 37 being provided on the wiring layer 36, the plurality of metal pads 38 being provided on these via plugs 37. The metal pads 38 are a Cu (copper) layer or an Al (aluminum) layer, for example. The circuit chip 2 serves as a control circuit (logic circuit) that controls the operation of the array chip 1. This control circuit is constituted of the transistors 31 and the like, and is electrically connected to the metal pads 38.

The array chip 1 includes a plurality of metal pads 41 and a plurality of via plugs 42, the plurality of metal pads 41 being provided on the metal pads 38, the plurality of via plugs 42 being provided on the metal pads 41. The array chip 1 also includes a wiring layer 43 and a wiring layer 44, the wiring layer 43 being provided on these via plugs 42, and including a plurality of wirings, the wiring layer 44 being provided above the wiring layer 43 and including a plurality of wirings. The metal pads 41 are a Cu layer or an Al layer, for example.

The array chip 1 further includes a plurality of via plugs 45, a metal pad 46, and a passivation film 47, the plurality of via plugs 45 being provided on the wiring layer 44, the metal pad 46 being provided on these via plugs 45 and the insulation film 12, the passivation film 47 being provided on the metal pad 46 and the insulation film 12. The metal pad 46 is a Cu layer or an Al layer, for example, and serves as an external connection pad (bonding pad) of the semiconductor device shown in FIG. 1. The passivation film 47 is, for example, an insulation film, such as a silicon oxide film, and has an opening P that causes the upper surface of the metal pad 46 to be exposed. The metal pad 46 can be connected to a mounting substrate or other devices by bonding wires, solder balls, metal bumps, or the like via this opening P.

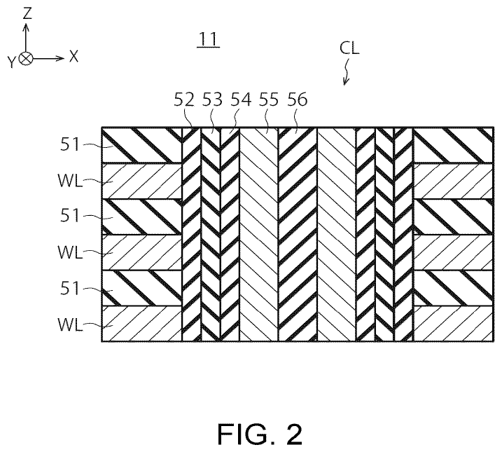

FIG. 2 is a cross sectional view showing one example of the structure of the column CL.

As shown in FIG. 2, the memory cell array 11 includes the plurality of word lines WL and a plurality of insulation layers 51 which are alternately laminated at a position above the interlayer insulation film 13 (FIG. 1). The word lines WL are W (tungsten) layers, for example. The insulation layers 51 are silicon oxide films, for example.

The column CL includes a block insulation film 52, a charge storage layer 53, a tunnel insulation film 54, a channel semiconductor layer 55, and a core insulation film 56 in the order. The charge storage layer 53 is a silicon nitride film, for example, and is formed on the side surfaces of the word lines WL and the insulation layers 51 with the block insulation film 52 interposed therebetween. The charge storage layer 53 may be a semiconductor layer, such as a polysilicon layer. The channel semiconductor layer 55 is a polysilicon layer, for example, and is formed on the side surface of the charge storage layer 53 with the tunnel insulation film 54 interposed therebetween. The block insulation film 52, the tunnel insulation film 54, and the core insulation film 56 are silicon oxide films or metal insulation films, for example.

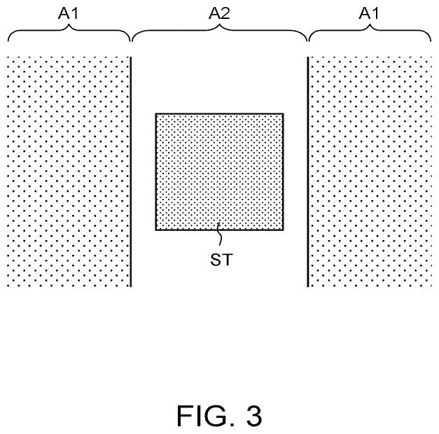

FIG. 3 is a top plan view showing one example of the configuration of the semiconductor device according to the first embodiment. FIG. 3 shows a portion of a wafer before being cut into individual pieces for the array chips 1 or the circuit chips 2. Values of dimensions, such as heights, thicknesses, and widths, which will be described below are merely examples.

A configuration shown in FIG. 1 and including semiconductor elements, such as the memory cell array 11 and the transistors 31, is provided in each of device regions A1 shown in FIG. 3. A measurement site ST is provided in a scribe line A2. The measurement site ST is a region in which an optical measurement method which will be described later, such as an optical critical dimension (OCD) method, is performed.

A configuration similar to the configuration provided in the device region A1 is provided in the scribe line A2.

The device region A1 is divided by the scribe line A2 having a width of 70 μm. The measurement site ST in 50 μm square is disposed in the scribe line A2. In the present embodiment, the entire measurement site ST is a measurement region. The measurement region is a region in which measurement is actually performed at the measurement site ST, and there may be cases in which the measurement region changes depending on conditions of measurement or other factors.

To effectively use the device regions A1, it is desirable that the measurement site ST shown in the present embodiment be disposed in the scribe line A2. Even when the measurement site ST is disposed in the scribe line A2, by installing a light blocking structure, a complicated structure duplicating the device region A1 can be formed as the lower layer structure in the measurement region and hence, it is possible to increase accuracy in process control.

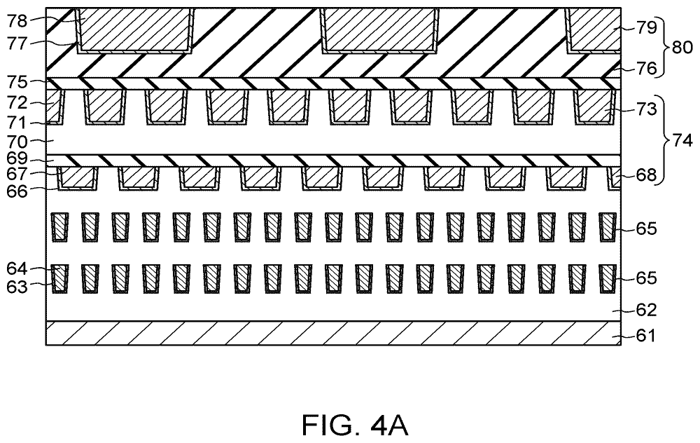

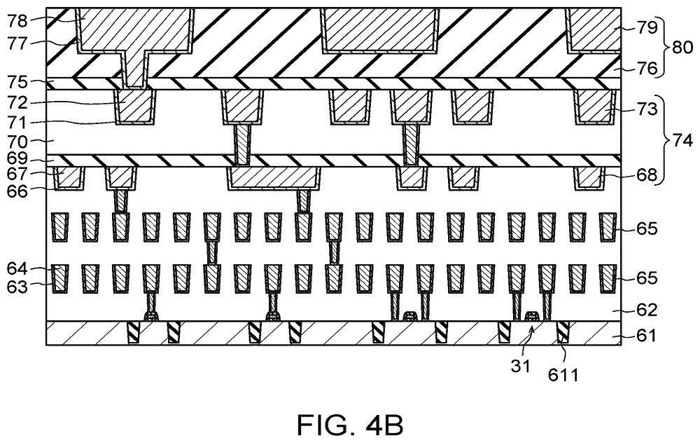

FIG. 4A and FIG. 4B are cross sectional views showing one example of the configuration of the semiconductor device according to the first embodiment.

FIG. 4A is a cross sectional view of a semiconductor device at the measurement site ST.

A silicon oxide (SiO₂) film is formed, as an insulation film 62, on a substrate 61 (for example, a semiconductor substrate, such as a silicon substrate), and a plurality of lower layer wirings 65 are formed in the insulation film 62, each lower layer wiring 65 being constituted of a barrier metal film 63 containing titanium nitride (TiN) and a conductive member 64 containing tungsten (W). A first light blocking layer 68 having a height of 100 nm is formed above the lower layer wirings 65, the first light blocking layer 68 being constituted of a barrier metal film 66 containing titanium nitride (TiN) and a wiring member 67 containing copper (Cu). A silicon nitrocarbide (SiCN) film having a thickness of 50 nm is formed, as a first cap film 69, on the first light blocking layer 68. A silicon oxide (SiO₂) film is formed, as an insulation film 70, on the first cap film 69. A second light blocking layer 73 having a height of 160 nm is formed in the insulation film 70, the second light blocking layer 73 being constituted of a barrier metal film 71 containing titanium nitride (TiN) and a wiring member 72 containing copper (Cu). A light blocking structure 74 is constituted of the first light blocking layer 68 and the second light blocking layer 73, and the first light blocking layer 68 and the second light blocking layer 73 are disposed such that at least either one of the first light blocking layer 68 or the second light blocking layer 73 is present over the entire measurement region as viewed from above. A silicon nitrocarbide (SiCN) film having a thickness of 50 nm is formed, as a second cap film 75, on the second light blocking layer 73. A silicon oxide (SiO₂) film having a thickness of 300 nm is formed, as an upper layer insulation film 76, on the second cap film 75. Upper layer wirings 79 having a height of 200 nm are formed in the upper layer insulation film 76, each upper layer wiring 79 being constituted of a barrier metal film 77 containing titanium nitride (TiN) and a wiring member 78 containing copper (Cu). An upper layer structure 80 being a measurement object is constituted of the upper layer insulation film 76 and the upper layer wirings 79.

FIG. 4B is a cross sectional view of a semiconductor device in the device region A1. FIG. 4B is a cross sectional view of a circuit chip C2, for example.

In the device region A1 shown in FIG. 4B, the transistors 31, the contact plugs, and the via plugs, and the like are further provided. The substrate 61 further includes element isolation regions 611.

The lower layer wirings 65 may be provided in one layer, or may be provided in three or more layers. In addition, the transistors 31 and the element isolation regions 611 may be provided below the lower layer wirings 65.

As shown in FIG. 4A and FIG. 4B, the heights (positions) and the materials of the lower layer wirings 65, the first light blocking layer 68, the second light blocking layer 73, and the upper layer wirings 79 are the same between the device region A1 and the scribe line A2.

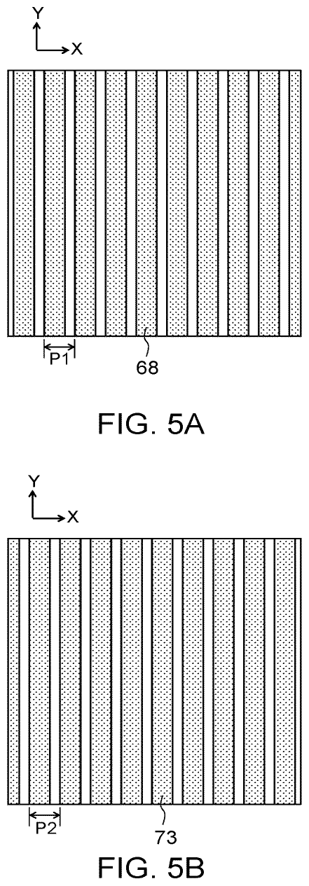

FIG. 5A and FIG. 5B are top plan views showing one example of the configuration of the light blocking structure 74 according to the first embodiment. FIG. 5A shows the layout of the first light blocking layer 68, and FIG. 5B shows the layout of the second light blocking layer 73.

The first light blocking layer 68 is formed in a line pattern (lines and spaces) in which lines having a width of 160 nm and spaces having a width of 80 nm are alternately installed along the X direction at a repetition pitch P1 of 240 nm. In the same manner, the second light blocking layer 73 is also formed in a line pattern in which lines having a width of 160 nm and spaces having a width of 80 nm are alternately installed along the X direction at a repetition pitch P2 of 240 nm. To block incident light by the light blocking structure 74, the first light blocking layer 68 and the second light blocking layer 73 are disposed such that at least the first light blocking layer 68 or the second light blocking layer 73 is present over the entire measurement region. That is, the first light blocking layer 68 and the second light blocking layer 73 are alternatively arranged, thus being arranged without forming any gaps as viewed from the Z direction.

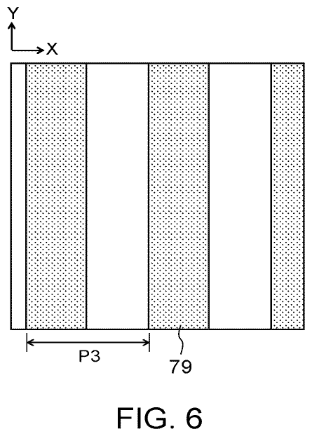

FIG. 6 is a top plan view showing one example of the configuration of the upper layer wirings 79 according to the first embodiment.

The upper layer wirings 79 are formed in a line pattern in which lines having a width of 480 nm and spaces having a width of 480 nm are alternately installed along the X direction at a repetition pitch P3 of 960 nm.

The first light blocking layer 68, the second light blocking layer 73, and the upper layer wirings 79 form a repeated structure in the X direction at a pitch of 960 nm, being the least common multiple of the repetition pitches of the respective layers.

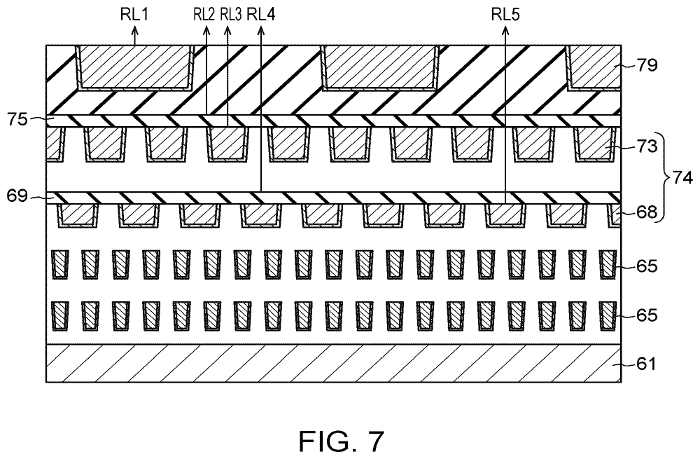

FIG. 7 is a top plan view showing one example of the configuration of the semiconductor device according to the first embodiment. FIG. 7 is a schematic view of a case in which the upper layer structure 80 in the measurement region is optically measured by the OCD method. In the OCD method, by obtaining the spectrum of reflected light of irradiated light, it is possible to measure a wiring depth, a structure pattern, and the like from the spectrum. The OCD method is performed at the measurement site ST.

Incident light (not shown in the drawing) emitted from above from the light source of a measuring instrument is reflected on interfaces in the respective layers in the measurement region. The shape of the upper layer structure is measured by detecting a reflection spectrum by the sensor of the measuring instrument. The reflected light is constituted of first reflected light RL1, second reflected light RL2, third reflected light RL3, fourth reflected light RL4, and fifth reflected light RL5, the first reflected light RL1 being reflected on the upper surface of the upper layer wiring 79, the second reflected light RL2 being reflected on the upper surface of the second cap film 75, the third reflected light RL3 being reflected on the upper surface of the second light blocking layer 73, the fourth reflected light RL4 being reflected on the upper surface of the first cap film 69, the fifth reflected light RL5 being reflected on the upper surface of the first light blocking layer 68. Incident light is blocked by the light blocking structure 74 constituted of the first light blocking layer 68 and the second light blocking layer 73, thus being prevented from reaching the lower layer wiring 65 or the substrate 61 and hence, it is possible to prevent a situation in which a reflection spectrum is made complicated by reflection from the lower layer wiring 65 or the substrate 61. Accordingly, it is possible to facilitate the formation of a measurement recipe, and to reduce time for measurement.

That is, at the measurement site ST that is irradiated with measurement light to measure the structure of the upper layer structure 80 (structural body), the light blocking structure 74 (light blocker) is provided at a position farther than the upper layer structure 80 in the advancing direction of the measurement light with which irradiation is performed. To be more specific, in the measurement site ST, the light blocking structure 74 is provided at a position farther than the upper layer wirings 79 in the advancing direction of the measurement light with which irradiation is performed. The light blocking structure 74 includes light blocking layers (metal layers) in two or more layers. To be more specific, the first light blocking layer 68 and the second light blocking layer 73 are alternately arranged to block measurement light, thus being arranged without forming any gaps as viewed from the Z direction. Consequently, the light blocking structure 74 is disposed in such a way as to cover the entire measurement site ST.

The light blocking structure 74 includes the light blocking layers in two or more layers. Consequently, it is possible to reduce a risk of dishing or of peeling of the film. In the case in which the light blocking structure 74 includes a light blocking layer having one layer over the entire measurement region, a large metal region is formed and hence, there arises a risk of dishing or of peeling of the film. Compared with such a case, in the case in which the light blocking structure 74 includes the light blocking layers in two or more layers, the occupancy ratio of the metal region for each layer can be reduced and hence, it is possible to reduce a risk of dishing or of peeling of the film.

Next, a method for manufacturing a semiconductor device will be described.

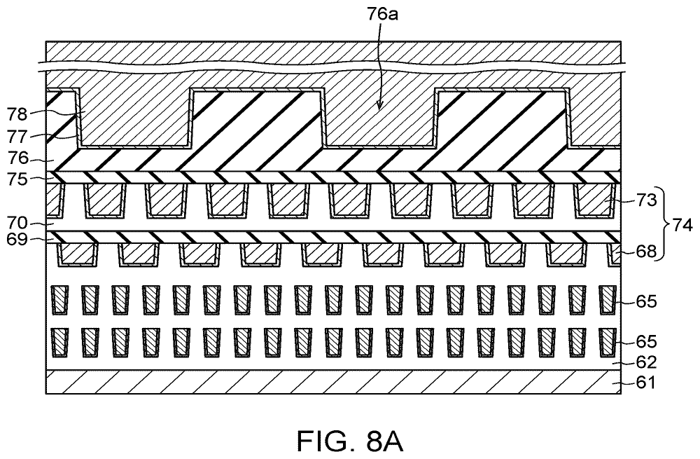

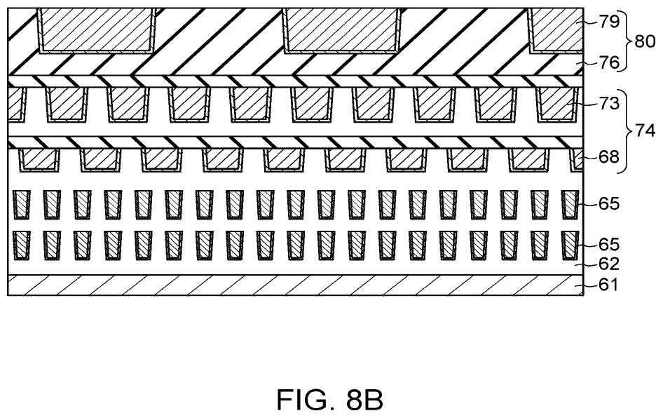

FIG. 8A and FIG. 8B are cross sectional views showing one example of the method for manufacturing the semiconductor device according to the first embodiment.

FIG. 8A is a cross sectional view of the measurement region in the measurement site ST provided to the semiconductor device before the CMP process.

Wiring grooves 76a having a depth of 250 nm are formed at the upper part of an upper layer insulation film 76. A 10 nm barrier metal film 77 containing titanium nitride (TiN) and a 500 nm wiring member 78 containing copper (Cu) are formed at the upper part of the upper layer insulation film 76.

FIG. 8B is a cross sectional view of the measurement region of the semiconductor device after the CMP process.

The barrier metal film 77 containing titanium nitride (TiN) and the wiring member 78 containing copper (Cu), which are formed at the upper part of the upper layer insulation film 76, are removed by polishing in the CMP process, and a portion of the upper layer insulation film 76 is further removed, thus forming an upper layer wiring 79 having a height of 200 nm. To control the finished shapes of the upper layer wiring 79 and the upper layer insulation film 76, the measurement region in the measurement site ST is optically measured by the OCD method.

By blocking reflected light from a lower layer wiring 65 or a substrate 61 by a light blocking structure 74, it is possible to prevent a reflection spectrum from becoming complicated. Consequently, it is possible to measure, with higher accuracy, the structure of an upper layer structure 80 used for control after the CMP. As a result, it is possible to facilitate the formation of a measurement recipe, and to reduce time for measurement.

The OCD method may be performed in a CMP device by using a measurement device installed in the CMP device, or may be performed by using a different measurement device. The description has been made for the example in which the OCD method is performed after the CMP. However, the OCD method may be performed before the CMP process to measure the shape before the CMP process.

The description has been made for the case in which the OCD method is adopted for the optical measurement method. Instead of the OCD method, measurement may be performed by other optical measurement methods, such as an optical interference type film thickness measurement method or spectroscopic ellipsometry.

As described above, according to the first embodiment, at the measurement site ST, the light blocking structure 74 is provided at a position farther than the upper layer structure 80 in the advancing direction of the measurement light with which irradiation is performed, and the light blocking structure 74 blocks the measurement light. By installing, at the measurement site ST, the light blocking layers formed of a plurality of patterned metal layers, it is possible to prevent intrusion of light into a layer disposed below the light blocking layer. Consequently, it is possible to prevent a situation in which a spectrum is made complicated by reflected light from the structure disposed below the upper layer structure 80, for example, from the lower layer wiring 65. Accordingly, it is possible to simplify the formation of a measurement recipe, and to reduce time for measurement.

In addition, the light blocking structure 74 includes light blocking layers in two or more layers. Consequently, it is possible to reduce a risk of dishing or of peeling of the film.

To block incident light by the light blocking structure 74, it is desirable to design the light blocking structure 74 such that a metal layer having a thickness of 80 nm or more is present over the entire measurement region (the light blocking structure 74). That is, by setting the total thickness of metal layers included in the light blocking structure 74 at an arbitrary position in the measurement region to 80 nm or more, it is possible to block incident light. As viewed from the Z direction, there are positions at which the first light blocking layer 68 and the second light blocking layer 73 overlap with each other and do not overlap with each other. At such positions having a small number of overlapping metal layers as viewed from the Z direction, the total thickness of the metal layers is small compared with the positions having a large number of overlapping layers. However, at an arbitrary position in the measurement region, the total thickness of the metal layers is 80 nm or more even at a position having a small number of overlapping metal layers. The thickness of 80 nm is merely an example of a predetermined thickness, and may be changed depending on an optical measurement method, or conditions of the optical measurement method or other factors, for example.

Although the light blocking structure 74 may be made of any metal, to simplify a process for manufacturing a semiconductor device, it is desirable that the light blocking structure 74 be made of metal containing at least one of Cu, W, Mo, Co, Al, Ru, Ti, or Ta used as a wiring material.

In order to perform measurement more efficiently, it is desirable that the pattern of each metal layer constituting the light blocking structure 74 is a repeated pattern to simplify the measurement model. Although the pattern of each metal layer constituting the light blocking structure 74 may be a shape pattern other than a line pattern, in such a case, it is desirable that the pattern is a repeated pattern in both the X direction and the Y direction. Although the patterns of the respective metal layers constituting the light blocking structure 74 may differ from each other, it is desirable to make a design that reduces the least common multiple of the pitches of the repeated patterns in the respective layers. More specifically, it is desirable that the least common multiple of the pitches of the repeated patterns in the respective layers be four times or less of the largest pitch of the pitches of the repeated patterns in the respective layers. It is also desirable that the least common multiple of the pitches of the repeated patterns in the respective layers be 5 μm or less. The numerical value of the least common multiple may be changed depending on the size (for example, 20 μm) of the irradiation range that is irradiated with measurement light.

As will be described in the following embodiment, the upper layer structure 80 may be constituted of only an upper layer insulation film 76 including no upper layer wirings 79. Alternatively, the upper layer structure 80 may be formed of a plurality of laminated insulation films, or a plurality of laminated upper layer wirings 79.

In the case of forming the upper layer wirings 79 in the upper layer structure 80, to perform measurement more efficiently, it is desirable that each layer forming the upper layer wirings 79 is formed in a repeated pattern to simplify the measurement model. Although each layer forming the upper layer wirings 79 may be formed in a shape pattern other than a line pattern, in such a case, it is desirable that each layer is formed in a repeated pattern in both the X direction and the Y direction. That is, it is desirable that the pattern of each metal layer constituting the light blocking structure 74, and the pattern of each metal layer constituting the upper layer wiring 79 be repeated patterns. Although the patterns of the respective metal layers constituting the upper layer wiring 79 may differ from each other, it is desirable to make a design that reduces the least common multiple of the pitches of the repeated patterns in the respective metal layers forming the upper layer wiring 79 and in the respective metal layers constituting the light blocking structure 74. More specifically, it is desirable that the least common multiple of the pitches of the repeated patterns in the respective layers be four times or less of the largest pitch of the pitches of the repeated patterns in the respective layers. It is also desirable that the least common multiple of the pitches of the repeated patterns in the respective layers be 5 μm or less. The numerical value of the least common multiple may be changed depending on the size (for example, 20 μm) of the irradiation range that is irradiated with measurement light.

Advantageous effects obtained by the light blocking structure 74 are particularly effective for the case in which the lower layer structure has a complicated reflection pattern. For example, in the case in which the lower layer structure has a metal wiring structure, such as the lower layer wirings 65, reflected light tends to become complicated due to reflection on the upper surface of the metal wiring. By installing the light blocking structure 74, it is possible to prevent reflected light from becoming complicated.

The measurement site ST is disposed at a plurality of positions on a wafer. As will be described in the following embodiment, depending on the position of the measurement site ST, at least one of the lower layer structure, the light blocking structure 74, or the upper layer structure 80 may have a different configuration.

### Second Embodiment

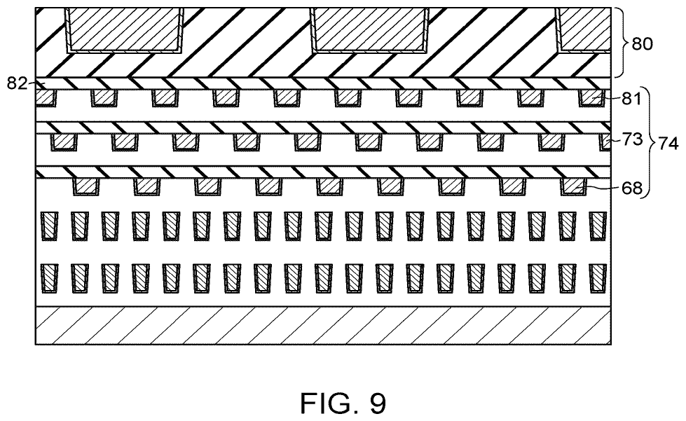

FIG. 9 is a cross sectional view showing one example of the configuration of a semiconductor device according to a second embodiment. The second embodiment differs from the first embodiment in that a light blocking structure 74 has a three layered structure.

The light blocking structure 74 is constituted of a first light blocking layer 68 having a height of 80 nm, a second light blocking layer 73 having a height of 80 nm, and a third light blocking layer 81 having a height of 80 nm, the third light blocking layer 81 being formed above the second light blocking layer 73 and being constituted of a barrier metal film containing titanium nitride (TiN) and a wiring member containing copper (Cu). A silicon nitrocarbide (SiCN) film having a thickness of 50 nm is formed, as a third cap film 82, on the third light blocking layer 81. An upper layer structure 80 being a measurement object is formed on the third cap film 82.

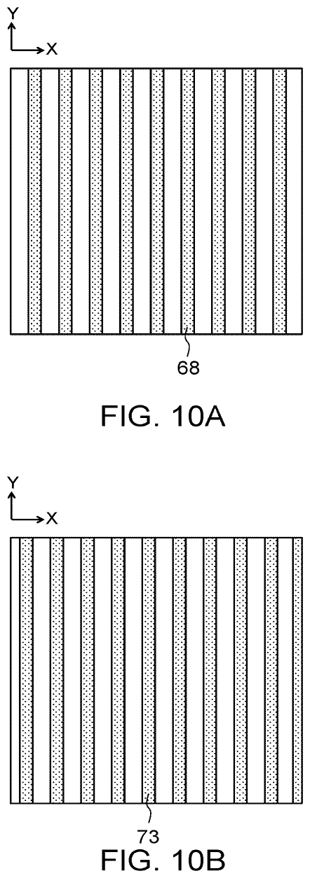

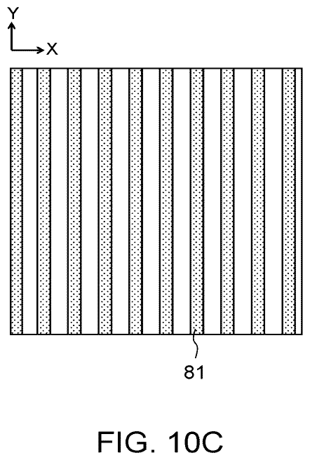

FIG. 10A to FIG. 10C are top plan views showing one example of the configuration of the light blocking structure 74 according to the second embodiment. FIG. 10A shows the layout of the first light blocking layer 68, FIG. 10B shows the layout of the second light blocking layer 73, and FIG. 10C shows the layout of the third light blocking layer 81.

Each of the first light blocking layer 68, the second light blocking layer 73, and the third light blocking layer 81 is formed in a line pattern in which lines having a width of 100 nm and spaces having a width of 140 nm are alternately installed along the X direction at a repetition pitch of 240 nm.

To block incident light by the light blocking structure 74, the first light blocking layer 68, the second light blocking layer 73, and the third light blocking layer 81 are disposed such that at least any one of these layers is present over the entire measurement region. That is, the first light blocking layer 68, the second light blocking layer 73, and the third light blocking layer 81 are arranged without forming any gaps as viewed from the Z direction.

The light blocking structure 74 may include light blocking layers in four or more layers.

As in the case of the second embodiment, the light blocking structure 74 may have a three layered structure. Also in this case, it is possible to obtain advantageous effects similar to those of the first embodiment.

### Third Embodiment

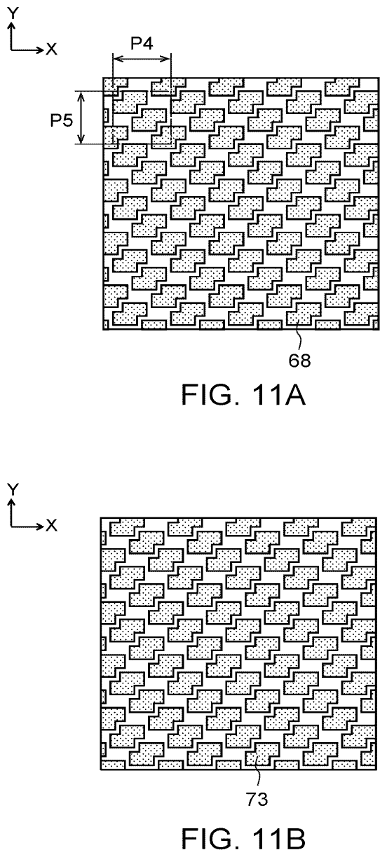

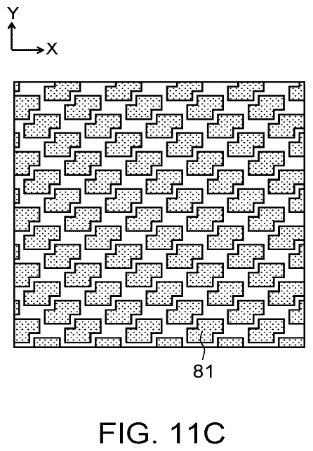

FIG. 11A to FIG. 11C are top plan views showing one example of the configuration of a light blocking structure 74 according to a third embodiment. FIG. 11A shows the layout of a first light blocking layer 68, FIG. 11B shows the layout of a second light blocking layer 73, and FIG. 11C shows the layout of a third light blocking layer 81. The third embodiment differs from the second embodiment in the pattern shape of the light blocking layers.

Each of the first light blocking layer 68, the second light blocking layer 73, and the third light blocking layer 81 is formed in a repeated pattern in which the layer is disposed at a repetition pitch P4 of 240 nm in the X direction, and is disposed at a repetition pitch P5 of 240 nm in the Y direction.

Also in the third embodiment, to block incident light by the light blocking structure 74 in the same manner as the second embodiment, the first light blocking layer 68, the second light blocking layer 73, and the third light blocking layer 81 are disposed such that at least any one of these layers is present over the entire measurement region.

As in the case of the third embodiment, the pattern shape of the light blocking layers may be changed. Also in this case, it is possible to obtain advantageous effects similar to those of the second embodiment.

### Fourth Embodiment

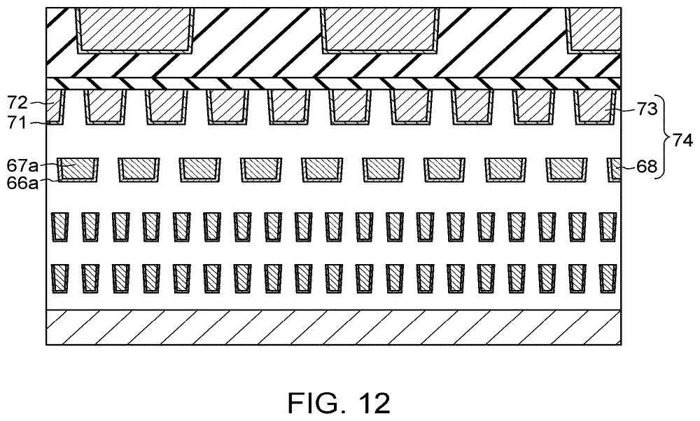

FIG. 12 is a cross sectional view showing one example of the configuration of a semiconductor device according to a fourth embodiment. The fourth embodiment differs from the first embodiment in that the material of a first light blocking layer 68 differs from the material of a second light blocking layer 73.

Light blocking layers in two or more layers respectively contain different metal materials of two or more kinds. The material of the first light blocking layer 68 and the material of the second light blocking layer 73 may be changed depending on the material of a metal layer in the same layer in a device region A1.

A light blocking structure 74 is constituted of the first light blocking layer 68 having a height of 100 nm and the second light blocking layer 73 having a height of 160 nm, the first light blocking layer 68 being formed of a barrier metal film 66a containing tungsten nitride (WN) and a wiring member 67a containing tungsten (W), the second light blocking layer 73 being constituted of a barrier metal film 71 containing titanium nitride (TiN) and a wiring member 72 containing copper (Cu). Depending on the material of the first light blocking layer 68, a first cap film 69 that prevents diffusion of copper (Cu) need not be provided.

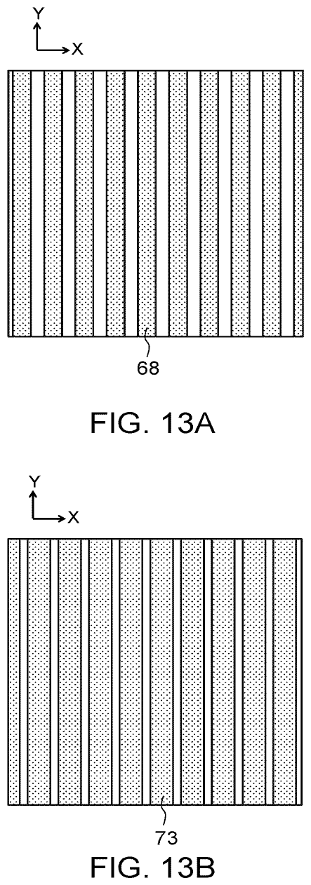

FIG. 13A and FIG. 13B are cross sectional views showing one example of the configuration of the light blocking structure 74 according to the fourth embodiment. FIG. 13A shows the layout of the first light blocking layer 68, and FIG. 13B shows the layout of the second light blocking layer 73.

The first light blocking layer 68 is formed in a line pattern in which lines having a width of 140 nm and spaces having a width of 100 nm are alternately installed along the X direction at a repetition pitch of 240 nm. The second light blocking layer 73 is formed in a line pattern in which lines having a width of 180 nm and spaces having a width of 60 nm are alternately installed along the X direction at a repetition pitch of 240 nm. That is, the wiring width of the first light blocking layer 68 may differ from the wiring width of the second light blocking layer 73.

As in the case of the fourth embodiment, the material of the first light blocking layer 68 may differ from the material of the second light blocking layer 73. Also in this case, it is possible to obtain advantageous effects similar to those of the first embodiment.

### Fifth Embodiment

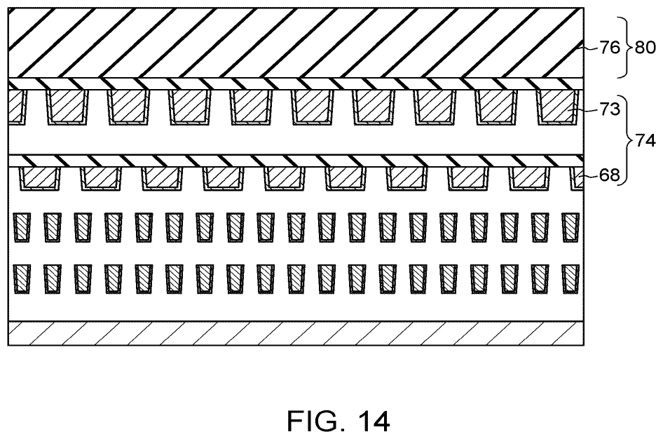

FIG. 14 is a cross sectional view showing one example of the configuration of a semiconductor device according to a fifth embodiment. The fifth embodiment differs from the first embodiment in that upper layer wirings 79 are not provided.

An upper layer structure 80 is constituted of only an upper layer insulation film 76 including no upper layer wiring 79.

As in the case of the fifth embodiment, the upper layer wirings 79 need not be provided. Also in this case, it is possible to obtain advantageous effects similar to those of the first embodiment.

### Sixth Embodiment

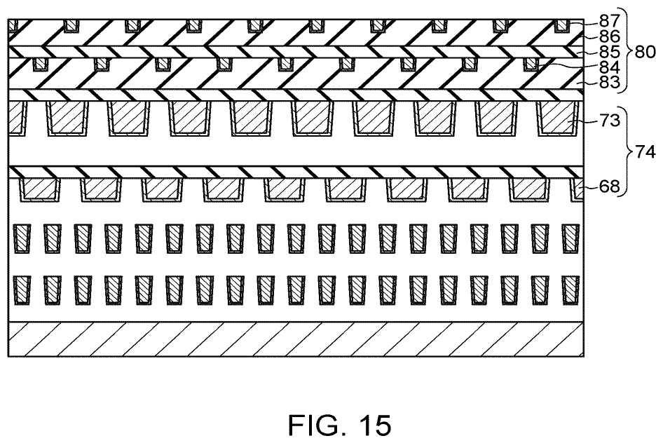

FIG. 15 is a cross sectional view showing one example of the configuration of a semiconductor device according to a sixth embodiment. The sixth embodiment differs from the first embodiment in the configuration of an upper layer structure 80.

The upper layer structure 80 is constituted of a first upper layer insulation film 83, first upper layer wirings 84 having a height of 50 nm, a fourth cap film 85, a second upper layer insulation film 86, and second upper layer wirings 87 having a height of 50 nm, the first upper layer insulation film 83 being a silicon oxide (SiO₂) film having a thickness of 140 nm, each first upper layer wiring 84 being constituted of a barrier metal film containing titanium nitride (TiN) and a wiring member containing copper (Cu), the fourth cap film 85 being a silicon nitrocarbide (SiCN) film having a thickness of 50 nm, the second upper layer insulation film 86 being a silicon oxide (SiO₂) film having a thickness of 110 nm, each second upper layer wiring 87 being constituted of a barrier metal film containing titanium nitride (TiN) and a wiring member containing copper (Cu).

As in the case of the sixth embodiment, the configuration of the upper layer structure 80 may be changed. Also in this case, it is possible to obtain advantageous effects similar to those of the first embodiment.

### Seventh Embodiment

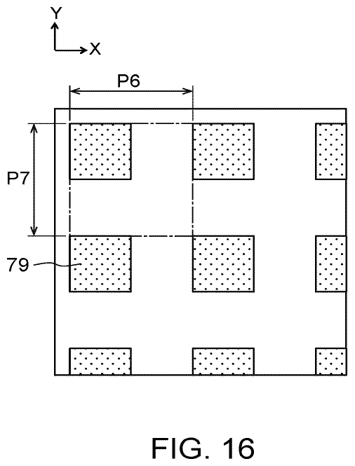

FIG. 16 is a top plan view showing one example of the configuration of a light blocking structure 74 according to a seventh embodiment. The seventh embodiment differs from the first embodiment in that each of upper layer wirings 79 is disposed in the form of a pad.

The upper layer wirings 79 are formed in a square pattern in which squares having a width of 480 nm and spaces having a width of 480 nm are alternately installed along the X direction at a repetition pitch P6 of 960 nm, and are alternately installed along the Y direction at a repetition pitch P7 of 960 nm.

The shape of the upper layer wirings 79 is not limited to a square shape.

As in the case of the seventh embodiment, each upper layer wiring 79 may be disposed in the form of a pad. Also in this case, it is possible to obtain advantageous effects similar to those of the first embodiment.

### Eighth Embodiment

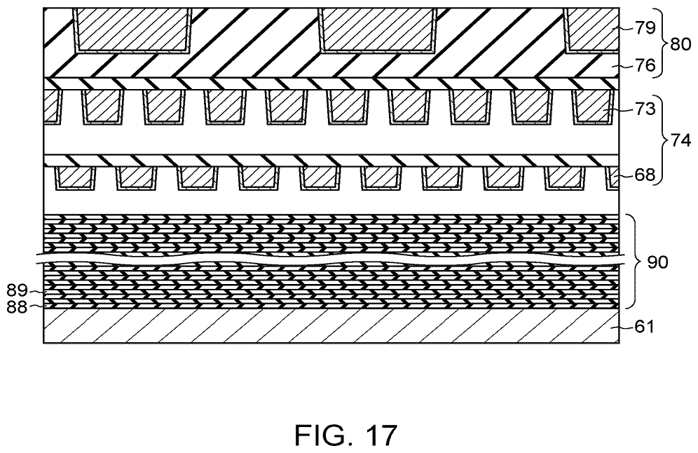

FIG. 17 is a cross sectional view showing one example of the configuration of a semiconductor device according to an eighth embodiment. The eighth embodiment differs from the first embodiment in that a stack is provided below a light blocking structure 74.

A stack 90 is provided in a device region A1 at the same height as a memory cell array 11.

The stack 90 is formed on a substrate 61, 64 layers of 20 nm insulation films 88 containing silicon oxide (SiO₂), and 64 layers of 20 nm insulation films 89 containing silicon nitride (Si₃N₄) are alternately laminated, that is, 128 layers are laminated in total. The light blocking structure 74 and an upper layer structure 80 are formed above the stack 90.

Advantageous effects obtained by the light blocking structure 74 are particularly effective for the case in which a lower layer structure has a complicated reflection pattern. For example, in the case of having a structure in which a large number of films having light transmission property are laminated, reflected light tends to become complicated due to reflection from a large number of laminated interfaces. By installing the light blocking structure 74, it is possible to prevent reflected light from becoming complicated.

In a process for manufacturing a three-dimensional flash memory, it is necessary to laminate films having light transmission property in fifty or more layers in order to form a memory cell array 11. It is also necessary to form light transmission films having a thickness of 2.5 μm or more in order to fill gaps formed between structures of the memory cell array 11. The thickness of 2.5 μm is merely an example of a predetermined thickness. The installation of the light blocking structure 74 is particularly effective in these structures.

The light blocking structure 74 can prevent a situation in which a spectrum is made complicated by reflected light from the structure disposed below the upper layer structure 80, for example, from a large number of interfaces. Accordingly, it is possible to simplify the formation of a measurement recipe, and to reduce time for measurement.

As in the case of the eighth embodiment, the stack may be provided below the light blocking structure 74. Also in this case, it is possible to obtain advantageous effects similar to those of the first embodiment.

### Ninth Embodiment

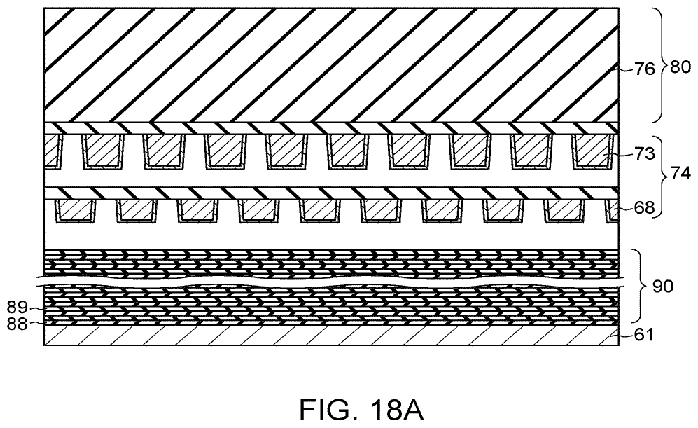

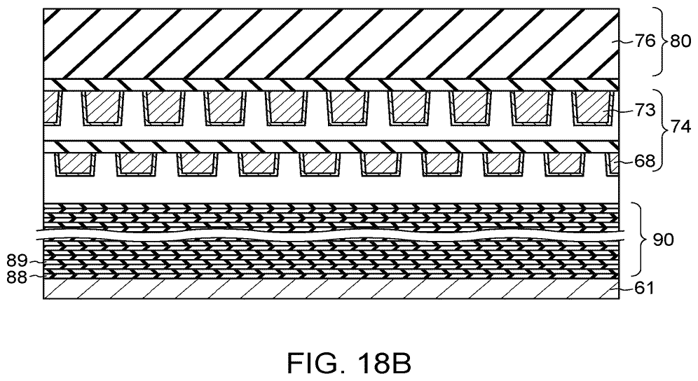

FIG. 18A and FIG. 18B are cross sectional views showing one example of a method for manufacturing a semiconductor device according to a ninth embodiment. The ninth embodiment differs from the eighth embodiment in that upper layer wirings 79 are not provided.

FIG. 18A is a cross sectional view of a measurement region in a measurement site ST provided to the semiconductor device before the CMP process.

The number of laminated layers of a stack 90 is set to be equal to the number of laminated layers of a memory cell array of a three-dimensional flash memory formed in a device region A1. The upper layer wirings 79 are not formed in an upper layer structure 80 being a measurement object, and is constituted of only an upper layer insulation film 76 having a thickness of 500 nm. To measure the thickness of the upper layer insulation film 76 before the CMP process, the measurement region in the measurement site ST is optically measured by the OCD method.

FIG. 18B is a cross sectional view of the measurement region of the semiconductor device after the CMP process.

Polishing is performed in the CMP process until the thickness of the upper layer insulation film 76 becomes 300 nm. To measure the thickness of the upper layer insulation film 76 after the CMP process, the measurement region in the measurement site ST is optically measured by the OCD method. The removal amount of the upper layer insulation film 76 per polishing time is calculated from the thicknesses of the upper layer insulation film 76 before and after the CMP process, and is managed as a process control item.

It is not always necessary to measure the measurement region in the measurement site ST before the CMP process.

As in the case of the ninth embodiment, the upper layer wirings 79 need not be provided. Also in this case, it is possible to obtain advantageous effects similar to those of the eighth embodiment.

### Tenth Embodiment

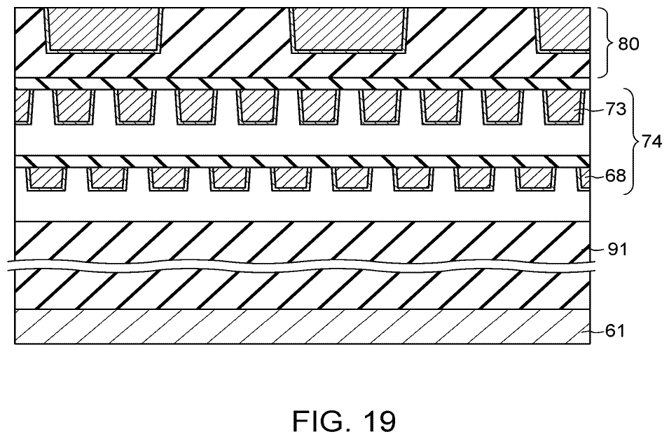

FIG. 19 is a cross sectional view showing one example of the configuration of a semiconductor device according to a tenth embodiment. The tenth embodiment differs from the first embodiment in that a film having light transmission property is provided below a light blocking structure 74.

A 3.4 μm film 91 containing silicon oxide (SiO₂) is formed on a substrate 61. The light blocking structure 74 and an upper layer structure 80 are formed above the film 91.

The film 91 is a film having light transmission property.

Advantageous effects obtained by the light blocking structure 74 are particularly effective also for the case in which a film having light transmission property and having a large thickness is present in a lower layer structure. In the case in which the film having light transmission property and having a large thickness is present in the lower layer structure, a large number of amplitude peaks occur in a reflection spectrum, so that a spectrum analysis becomes complicated, thus making it easy to cause an increase in time for measurement or cause erroneous measurements. By installing the light blocking structure 74, it is possible to reduce the occurrence of amplitude peaks.

The light blocking structure 74 can prevent a situation in which a spectrum is complicated by an increased spectrum oscillation caused by interference of the structure disposed below the upper layer structure 80, for example, of the film having light transmission property and having a large thickness. Accordingly, it is possible to simplify the formation of a measurement recipe, and to reduce time for measurement.

As in the case of the tenth embodiment, the film having light transmission property may be provided below the light blocking structure 74. Also in this case, it is possible to obtain advantageous effects similar to those of the first embodiment.

### Eleventh Embodiment

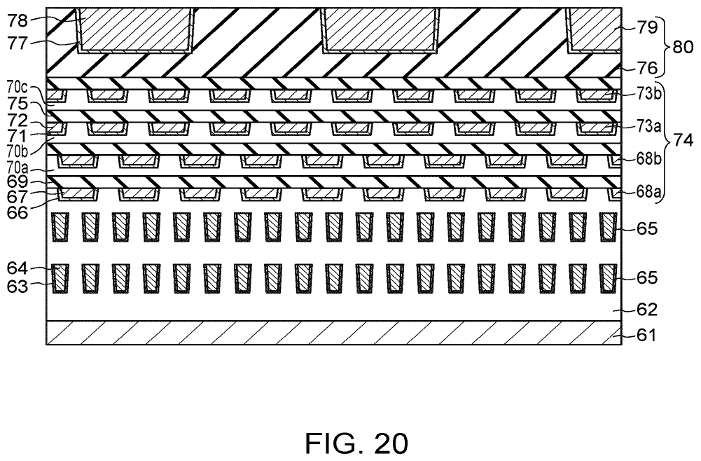

FIG. 20 is a cross sectional view showing one example of the configuration of a semiconductor device according to an eleventh embodiment. The eleventh embodiment differs from the first embodiment in that each of a first light blocking layer 68 and a second light blocking layer 73 is disposed in a state of being divided into two layers.

A silicon oxide (SiO₂) film is formed, as an insulation film 62, on a substrate 61 (a semiconductor substrate, such as a silicon substrate, for example), and a plurality of lower layer wirings 65 are formed in the insulation film 62, each lower layer wiring 65 being constituted of a barrier metal film 63 containing titanium nitride (TiN) and a conductive member 64 containing tungsten (W). A first divided light blocking layer 68a having a height of 50 nm is formed above the lower layer wirings 65, the first divided light blocking layer 68a being constituted of a barrier metal film 66 containing titanium nitride (TiN) and a wiring member 67 containing copper (Cu). A silicon nitrocarbide (SiCN) film having a thickness of 50 nm is formed, as a first cap film 69, on the first divided light blocking layer 68a. A silicon oxide (SiO₂) film is formed, as an insulation film 70a, on the first cap film 69. A second divided light blocking layer 68b having a height of 50 nm is formed in the insulation film 70a, the second divided light blocking layer 68b being constituted of a barrier metal film 66 containing titanium nitride (TiN) and a wiring member 67 containing copper (Cu). A silicon nitrocarbide (SiCN) film having a thickness of 50 nm is formed, as a first cap film 69, on the second divided light blocking layer 68b. A silicon oxide (SiO₂) film is formed, as an insulation film 70b, on the first cap film 69. A third divided light blocking layer 73a having a height of 50 nm is formed in the insulation film 70b, the third divided light blocking layer 73a being constituted of a barrier metal film 71 containing titanium nitride (TiN) and a wiring member 72 containing copper (Cu). A silicon nitrocarbide (SiCN) film having a thickness of 50 nm is formed, as a second cap film 75, on the third divided light blocking layer 73a. A silicon oxide (SiO₂) film is formed, as an insulation film 70c, on the second cap film 75. A fourth divided light blocking layer 73b having a height of 50 nm is formed in the insulation film 70c, the fourth divided light blocking layer 73b being constituted of a barrier metal film 71 containing titanium nitride (TiN) and a wiring member 72 containing copper (Cu). A light blocking structure 74 is constituted of the first divided light blocking layer 68a, the second divided light blocking layer 68b, the third divided light blocking layer 73a, and the fourth divided light blocking layer 73b. The first divided light blocking layer 68a, the second divided light blocking layer 68b, the third divided light blocking layer 73a, and the fourth divided light blocking layer 73b are disposed such that at least any one of these layers is present over the entire measurement region as viewed from above. A silicon nitrocarbide (SiCN) film having a thickness of 50 nm is formed, as a second cap film 75, on the fourth divided light blocking layer 73b. A silicon oxide (SiO₂) film having a thickness of 300 nm is formed, as an upper layer insulation film 76, on the second cap film 75. Upper layer wirings 79 having a height of 200 nm are formed in the upper layer insulation film 76, each upper layer wiring 79 being constituted of a barrier metal film 77 containing titanium nitride (TiN) and a wiring member 78 containing copper (Cu). An upper layer structure 80 being a measurement object is constituted of the upper layer insulation film 76 and the upper layer wirings 79.

The thickness of each of the first divided light blocking layer 68a, the second divided light blocking layer 68b, the third divided light blocking layer 73a, and the fourth divided light blocking layer 73b is smaller than 80 nm. However, the total thickness of the metal layers at an arbitrary position in the measurement region is 80 nm or more. The reason for this is that the minimum value of the number of overlapping metal layers as viewed from the Z direction is two. As described above, a plurality of metal layers having relatively small thicknesses may be provided such that the total thickness of the metal layers at an arbitrary position in the measurement region is 80 nm or more.

Although each of the first light blocking layer 68 and the second light blocking layer 73 is divided into two, such a number is merely an example, and the number of division is not limited to two. In addition, the total number of metal layers is not limited to four.

As in the case of the eleventh embodiment, each of the first light blocking layer 68 and the second light blocking layer 73 may be disposed in a state of being divided into two layers. Also in this case, it is possible to obtain advantageous effects similar to those of the first embodiment.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a structural body; and
a light blocker provided at a measurement site that is irradiated with measurement light to measure a structure of the structural body, the light blocker being provided at a position farther than the structural body in an advancing direction of the measurement light with which irradiation is performed, and being configured to block the measurement light, wherein
the light blocker includes first metal layers in two or more layers.

2. The semiconductor device according to claim 1, wherein a total thickness of the first metal layers in two or more layers is 80 nm or more over an entire light blocker in the measurement site.

3. The semiconductor device according to claim 1, wherein the first metal layers in two or more layers contain at least one of Cu, W, Mo, Co, Al, Ru, Ti, or Ta.

4. The semiconductor device according to claim 1, further comprising a substrate above which the structural body and the light blocker are provided, wherein
the first metal layers in two or more layers have repeated patterns in either one of a first direction or a second direction, or in both the first direction and the second direction, the first direction and the second direction being substantially parallel to the substrate and being perpendicular to each other.

5. The semiconductor device according to claim 4, wherein a least common multiple of pitches of the repeated patterns in the first metal layers in two or more layers is four times or less of a largest pitch.

6. The semiconductor device according to claim 4, wherein a least common multiple of pitches of the repeated patterns in the first metal layers in two or more layers is 5 μm or less.

7. The semiconductor device according to claim 1, wherein the structural body includes a second metal layer having a predetermined pattern, and
the light blocker is provided at a position farther than the second metal layer in the advancing direction of the measurement light with which irradiation is performed.

8. The semiconductor device according to claim 7, further comprising a substrate above which the structural body and the light blocker are provided, wherein
the first metal layers in two or more layers and the second metal layer have repeated patterns in either one of a first direction or a second direction, or in both the first direction and the second direction, the first direction and the second direction being substantially parallel to the substrate, and being perpendicular to each other.

9. The semiconductor device according to claim 8, wherein a least common multiple of pitches of the repeated patterns in the first metal layers in two or more layers and the second metal layer is four times or less of a largest pitch.

10. The semiconductor device according to claim 8, wherein a least common multiple of pitches of the repeated patterns in the first metal layers in two or more layers and the second metal layer is 5 μm or less.

11. The semiconductor device according to claim 1, further comprising:
a substrate above which the structural body and the light blocker are provided; and
a film provided between the light blocker and the substrate, the film having a thickness of 2.5 μm or more and having light transmission property.

12. The semiconductor device according to claim 1, further comprising:
a substrate above which the structural body and the light blocker are provided; and
a stack provided between the light blocker and the substrate, the stack including fifty or more layers of laminated films having light transmission property.

13. The semiconductor device according to claim 1, further comprising:
a substrate above which the structural body and the light blocker are provided; and
a third metal layer provided between the light blocker and the substrate, the third metal layer being in at least one layer.

14. The semiconductor device according to claim 1, wherein the measurement site is disposed in a scribe line.

15. The semiconductor device according to claim 1, further comprising a semiconductor element disposed in a device region that is different from the measurement site, wherein
the semiconductor element includes
a memory cell array including a plurality of conductive layers and a plurality of insulation layers which are alternately laminated, and
a plurality of columns that penetrate through the memory cell array.

16. The semiconductor device according to claim 1, further comprising metal layers in two or more layers in a device region that is different from the measurement site, the metal layers in two or more layers being provided at same heights as and made of same materials as the first metal layers in two or more layers in the measurement site.

17. The semiconductor device according to claim 1, wherein the first metal layers in two or more layers respectively contain different metal materials of two or more kinds.

18. A method for manufacturing a semiconductor device including a structural body, and a light blocker provided at a measurement site that is irradiated with measurement light to measure a structure of the structural body, the light blocker being provided at a position farther than the structural body in an advancing direction of the measurement light with which irradiation is performed, the light blocker including first metal layers in two or more layers, the method comprising
measuring the structure of the structural body at the measurement site.

19. The method for manufacturing a semiconductor device according to claim 18, wherein the measuring the structure of the structural body includes measuring the structure of the structural body by an optical interference type film thickness measurement method, by spectroscopic ellipsometry, or by an optical critical dimension (OCD) method.

20. The method for manufacturing a semiconductor device according to claim 18, further comprising, before the measuring the structure of the structural body, polishing the structural body, or
further comprising, before the measuring the structure of the structural body,
measuring the structure of the structural body before being polished, and
polishing the structural body.

21. The method for manufacturing a semiconductor device according to claim 18, wherein
the semiconductor device further includes a semiconductor element disposed in a device region that is different from the measurement site, and
the semiconductor element includes
a memory cell array including a plurality of conductive layers and a plurality of insulation layers which are alternately laminated, and
a plurality of columns that penetrate through the memory cell array.
